(19) United States
(12) Patent Application Publication
(10) Pub. No.: US 2026/0198371 A1
(43) Pub. Date: Jul. 9, 2026

(54) ELECTRONIC DEVICE AND METHOD OF MANUFACTURING THE SAME

(71) Applicant: Advanced Semiconductor Engineering, Inc., Kaohsiung (TW)

(72) Inventors: Chao Wei LIU, Kaohsiung (TW); Meng-Wei HSIEH, Kaohsiung (TW); Fan-Yu MIN, Kaohsiung (TW)

(73) Assignee: Advanced Semiconductor Engineering, Inc., Kaohsiung (TW)

(21) Appl. No.: 19/290,285

(22) Filed: Aug. 4, 2025

Related U.S. Application Data
(60) Provisional application No. 63/743,590, filed on Jan. 9, 2025.

(51) Int. Cl. H01L 23/31; H01L 21/56; H01L 23/00; H01L 23/538; H01L 25/10; H01L 25/18; H10B 80/00; H10D 80/30

(52) U.S. Cl. CPC H10W 74/141; H10W 70/611; H10W 70/65; H10W 74/01; H10W 74/117; H10W 90/00; H10W 90/401; H10B 80/00; H10D 80/30; H10W 74/15; H10W 90/724; H10W 90/734

(57) ABSTRACT

The present disclosure provides an electronic device. The electronic device includes a redistribution layer (RDL) having a plurality of conductive pads, a chip disposed over the RDL, and an encapsulant disposed over the RDL. The encapsulant includes a first portion surrounding the chip and a second portion surrounding the plurality of conductive pads. The first portion and the second portion have different thicknesses. A method for manufacturing an electronic device is also provided.

### CROSS REFERENCE TO RELATED APPLICATION

This application claims the benefit of U.S. provisional application No. 63/743,590, filed Jan. 9, 2025, the content of which is incorporated herein by reference in its entirety.

### BACKGROUND

### 1. Technical Field

The present disclosure relates to an electronic device and a method of manufacturing an electronic device.

### 2. Description of the Related Art

A Fan-out Multi-Chip Module (FO-MCM) integrates multiple chips within a single encapsulant, using a redistribution layer (RDL) to fan out I/Os. However, conventional FO-MCMs often result in higher costs and lower yields, as damaged components cannot be removed or replaced once molding is complete.

### SUMMARY

In some arrangements, an electronic device includes a redistribution layer (RDL) having a plurality of conductive pads, a chip disposed over the RDL, and an encapsulant disposed over the RDL. The encapsulant includes a first portion surrounding the chip and a second portion surrounding the plurality of conductive pads. The first portion and the second portion have different thicknesses.

In some arrangements, an electronic device includes an RDL, a chip disposed over the RDL, an encapsulant covering the chip, and a memory package disposed over the RDL and uncovered by the encapsulant. The memory package extends past the encapsulant.

In some arrangements, a method for manufacturing an electronic device includes providing an RDL having a plurality of conductive pads, disposing a chip over the RDL, and forming an encapsulant covering the chip without covering the plurality of conductive pads.

### BRIEF DESCRIPTION OF THE DRAWINGS

Aspects of some arrangements of the present disclosure are best understood from the following detailed description when read with the accompanying figures. It should be noted that various structures may not be drawn to scale, and dimensions of the various structures may be arbitrarily increased or reduced for clarity of discussion.

FIG. 1A illustrates a cross-sectional view of an electronic device in accordance with some arrangements of the present disclosure.

FIG. 1A-1 illustrates a cross-sectional view of an electronic device in accordance with some arrangements of the present disclosure.

FIG. 1B illustrates a perspective view of an electronic device in accordance with some arrangements of the present disclosure.

FIG. 1C illustrates a perspective view of an electronic device in accordance with some arrangements of the present disclosure.

FIG. 1D illustrates a perspective view of an electronic device in accordance with some arrangements of the present disclosure.

FIG. 2A illustrates a cross-sectional view of an electronic device in accordance with some arrangements of the present disclosure.

FIG. 2A-1 illustrates a cross-sectional view of an electronic device in accordance with some arrangements of the present disclosure.

FIG. 2B illustrates a perspective view of an electronic device in accordance with some arrangements of the present disclosure.

FIG. 2C illustrates a perspective view of an electronic device in accordance with some arrangements of the present disclosure.

FIG. 3A illustrates a cross-sectional view of an electronic device in accordance with some arrangements of the present disclosure.

FIG. 3A-1 illustrates a cross-sectional view of an electronic device in accordance with some arrangements of the present disclosure.

FIG. 3B illustrates a perspective view of an electronic device in accordance with some arrangements of the present disclosure.

FIG. 3C illustrates a perspective view of an electronic device in accordance with some arrangements of the present disclosure.

FIG. 3D illustrates a perspective view of an electronic device in accordance with some arrangements of the present disclosure.

FIG. 4A illustrates a cross-sectional view of an electronic device in accordance with some arrangements of the present disclosure.

FIG. 4A-1 illustrates a cross-sectional view of an electronic device in accordance with some arrangements of the present disclosure.

FIGS. 5A, 5B, 5C, 5D, 5E, 5F, 5G, and 5H are cross-sections of one or more stages of a method of manufacturing an electronic device in accordance with some arrangements of the present disclosure.

### DETAILED DESCRIPTION

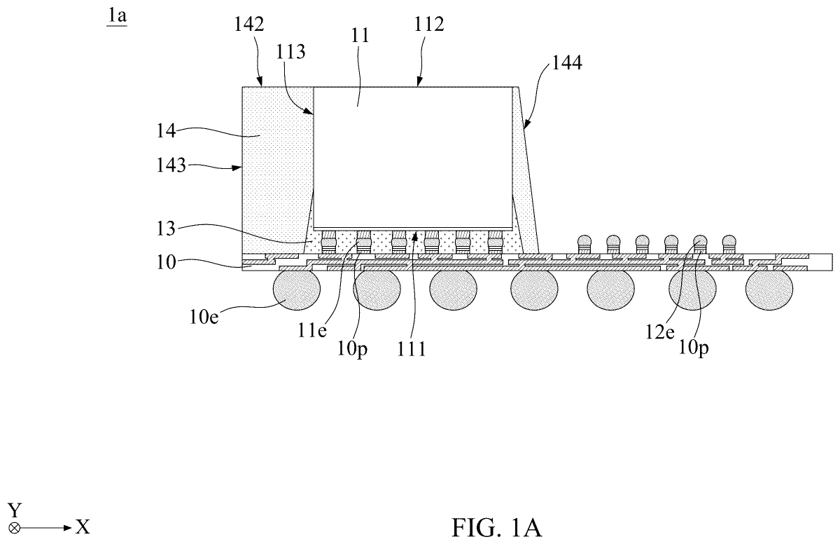

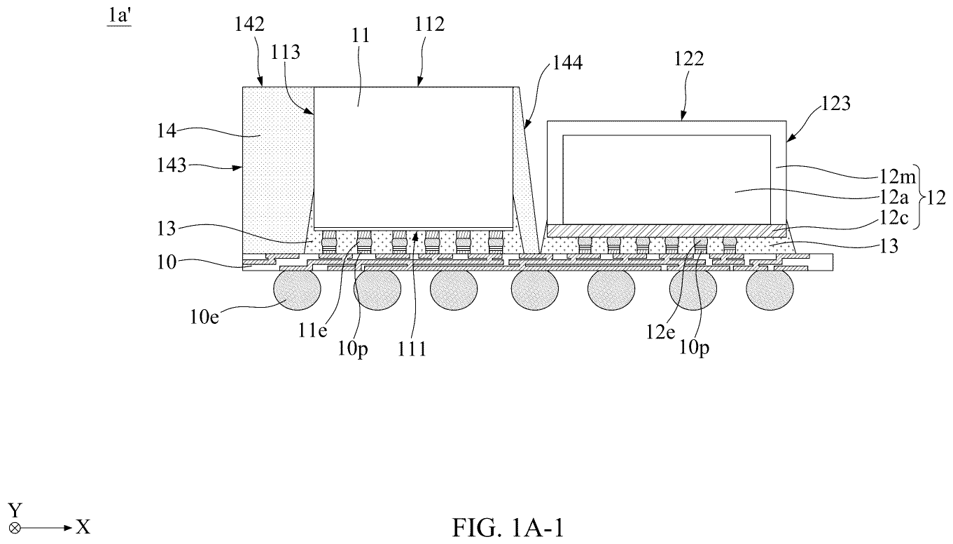

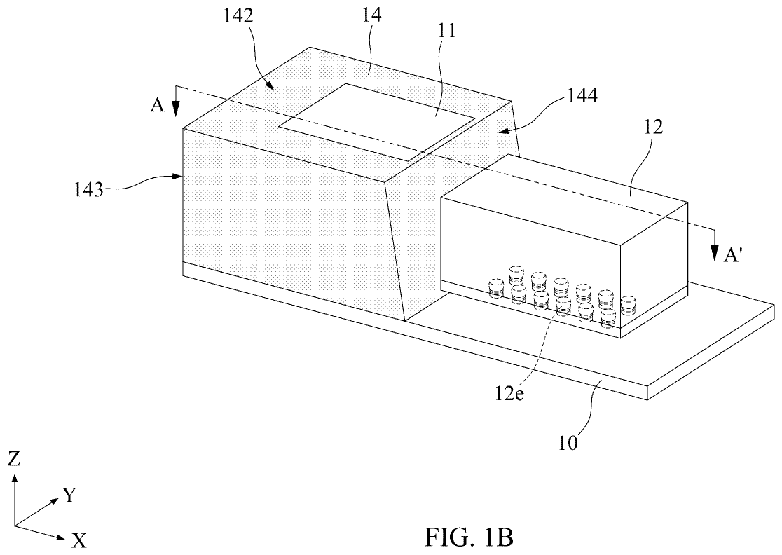

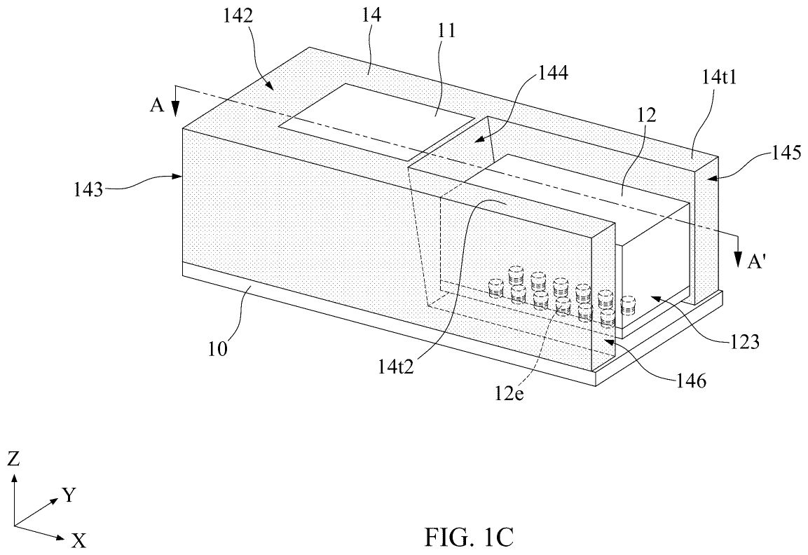

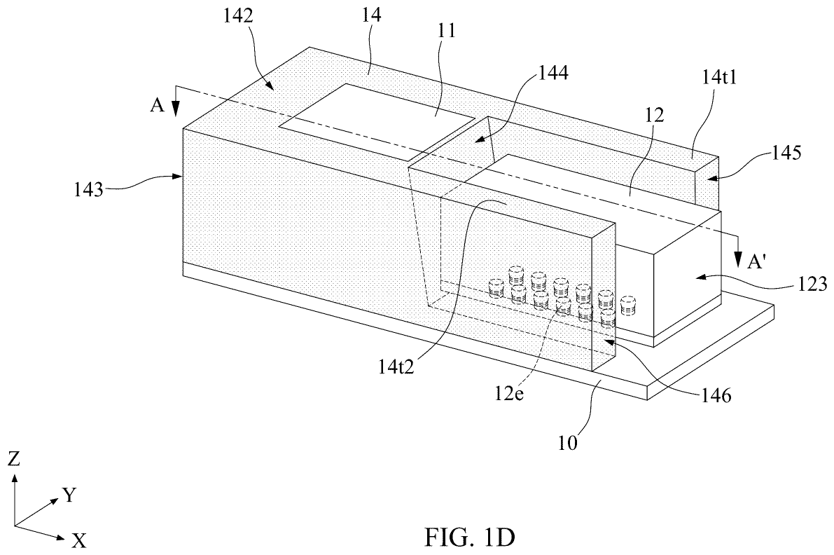

FIG. 1A illustrates a cross-sectional view of an electronic device 1a in accordance with some arrangements of the present disclosure. The electronic device 1a may include a package, such as an electronic device package. In some arrangements, the electronic device 1a may include a carrier 10, an electronic component 11, an underfill 13, and an encapsulant 14.

The carrier 10 may be configured to provide structural support for the electronic component 11, the underfill 13, and the encapsulant 14. In some arrangements, the carrier 10 may be configured to provide a power connection for the electronic component 11. In some arrangements, the carrier 10 may be configured to reroute or redistribute the input/output (I/O) connections of the electronic component 11 to a different layout that is more suitable for packaging or interconnection with other components. For example, the carrier 10 may be configured to reroute or redistribute the I/O connections of the electronic component 11 to a board (not illustrated in the figures) through electrical contacts 10e.

In some arrangements, the line spacing of the I/O connections of the electronic component 11 may be smaller or finer than that of the carrier 10. For example, the value range of the Line/Space (L/S) ratio of the I/O connections of the electronic component 11 may be smaller than that of the carrier 10.

The carrier 10 may include one or more redistribution layers (RDLs). For example, the carrier 10 may include one or more conductive layers and one or more dielectric layers. A portion of the conductive layer may be covered or encapsulated by the dielectric layer, while another portion of the conductive layer may be exposed from the dielectric layer to provide electrical connections. For example, the carrier 10 may include one or more conductive pads 10p. The conductive pad 10p may be at least partially exposed on a surface of the carrier 10.

The conductive layer may include a conductive material such as a metal or metal alloy. Examples of the conductive materials include gold (Au), silver (Ag), copper (Cu), platinum (Pt), palladium (Pd), other metals or alloys, or a combination of two or more of these. The dielectric layer may include a dielectric material, such as an epoxy-based material (e.g., epoxy resin with silica/alumina fillers), a molding compound (e.g., an epoxy molding compound or another type of molding compound), Ajinomoto build-up film (ABF), polyimide (PI), benzocyclobutene (BCB), silicon oxide, silicon nitride, etc. In some arrangements, the dielectric layer may include other suitable non-conductive materials or insulating materials.

The electronic component 11 may be disposed over the carrier 10. The electronic component 11 may be electrically connected to the carrier 10, and the electrical connections may be attained by way of solder bonding, Cu-to-Cu bonding, wire bonding, or hybrid bonding. For example, the electronic component 11 may be electrically connected with the conductive pads 10p of the carrier 10 through electrical contacts 11e.

The electronic component 11 may include a surface 111 facing the carrier 10, a surface 112 opposite to the surface 111, and a surface 113 extending between the surface 111 and the surface 112. The surface 111 may be an active surface, a front surface, or a front side. The surface 112 may be a backside surface or a backside. The surface 113 may be a lateral surface or a sidewall.

In some arrangements, the electronic component 11 may be a chip or a die including a semiconductor substrate, one or more integrated circuit (IC) devices and one or more overlying interconnection structures therein. The IC devices may include active devices such as transistors and/or passive devices such as resistors, capacitors, inductors, or a combination thereof. For example, the electronic component 11 may include a radio frequency integrated circuit (RFIC), an application-specific IC (ASIC), a central processing unit (CPU), a microprocessor unit (MPU), a graphics processing unit (GPU), a microcontroller unit (MCU), a field-programmable gate array (FPGA), or another type of IC. For example, the electronic component 11 may include a system on chip (SoC), a system-on-module (SoM), a system-in-package (SiP), or another type of IC that combines multiple components. Additionally, there may be any number of electronic components depending on design requirements.

In some arrangements, the electronic component 11 may include a computational array of multiple units processing values fetched from memory, and a hardware arbiter that synchronizes receipt of selected values by issuing a control signal to a control queue upon granting memory access.

The underfill 13 may be disposed between the carrier 10 and the electronic component 11. The underfill 13 may surround or cover the electrical contacts 11e. The underfill 13 may climb onto the surface 113 of the electronic component 11. In some arrangements, the climbing height (or the vertical coverage height, or the extension length) of the underfill 13 may vary. For example, the climbing height of the underfill 13 on the left side of the electronic component 11 may be less than that on the right side.

The underfill 13 may be liquid at room temperature and may have a relatively low viscosity for easy flow and filling of spaces or voids. In some arrangements, the underfill 13 may include an epoxy-based underfill, a silicone-based underfill, or a polyimide-based underfill. The underfill 13 may be chosen based on functions such as reducing mechanical stress, improving thermal cycling performance, and protecting solder joints. For example, the underfill 13 may be designed to have a low modulus and a low coefficient of thermal expansion (CTE), and to generate low stress during temperature cycling.

The encapsulant 14 may be disposed over the carrier 10. The encapsulant 14 may cover the electronic component 11 and the underfill 13. The encapsulant 14 may have a surface (such as a top surface) 142. The surface 112 of the electronic component 11 may be at least partially exposed from the encapsulant 14. The surface 112 of the electronic component 11 and the surface 142 of the encapsulant 14 may be substantially coplanar or aligned.

The encapsulant 14 may have a lateral surface (or a sidewall) 143 and a lateral surface (or a sidewall) 144 opposite to the lateral surface 143. The lateral surfaces 143 and 144 may not be parallel to each other. For example, the imaginary extension lines of the lateral surfaces 143 and 144 may form an angle, indicating that the surfaces are inclined relative to one another. For example, the lateral surface 143 may be substantially perpendicular to the carrier 10, and the lateral surface 144 may be inclined with respect to the carrier 10. For example, the lateral surface 143 may provide a vertical boundary, while the lateral surface 144 may provide a slanted or tapered profile.

In some arrangements, the lateral surface 143 of the encapsulant 14 may be substantially aligned with a lateral surface of the carrier 10, and the lateral surface 144 of the encapsulant 14 may extend over the carrier 10. For example, the lateral surface 144 of the encapsulant 14 may be located inside the outline or boundary of the carrier 10. For example, the encapsulant 14 may have a recessed or inset profile over the carrier 10.

In some arrangements, the encapsulant 14 may include an epoxy resin with fillers, a molding compound (e.g., an epoxy molding compound or another type of molding compound), a polyimide, a phenolic compound or material, a material with a silicone dispersed therein, or a combination thereof. In some arrangements, the encapsulant 14 may include a reinforcement, such as a reinforcement skeleton. In some arrangements, the encapsulant 14 may include a material different from that of the underfill 13.

In some arrangements, the underfill 13 may be omitted, potentially reducing manufacturing costs while maintaining adequate protection for the electronic component 11. For example, the encapsulant 14 may be disposed between the carrier 10 and the electronic component 11. The encapsulant 14 may surround or cover the electrical contacts 11e.

The electrical contacts 12e may be disposed over the conductive pads 10p of the carrier 10. In some arrangements, the electrical contacts 10e, 11e, and 12e may include solder balls or solder bumps, such as controlled collapse chip connection (C4) bumps, a ball grid array (BGA) or a land grid array (LGA). In some arrangements, the electrical contacts 10e, 11e, and 12e may reduce potential barriers for carriers at an interface between the carrier 10 and the other components.

The electrical contacts 12e may not be covered by the encapsulant 14. In some arrangements, the electrical contacts 12e may be configured to serve as a predefined location or mounting point for another component (such as the package 12 in FIG. 1A-1). For example, the electrical contacts 12e may be configured to connect the package 12 in FIG. 1A-1. This arrangement allows for selective protection of the carrier 10, potentially enhancing its mechanical stability and environmental resistance while maintaining access to certain areas for electrical connections. Additionally, it allows the placement of the package 12 to be postponed until after the molding operation is complete. By deferring this step, the process minimizes potential damage to the package 12 during molding and enhances the precision of die alignment, ultimately contributing to higher product reliability and efficiency.

FIG. 1A-1 illustrates a cross-sectional view of an electronic device 1a′ in accordance with some arrangements of the present disclosure. The electronic device 1a′ is similar to the electronic device 1a in FIG. 1A, except that the electronic device 1a′ further includes the package 12.

The package 12 may be disposed over the carrier 10. The underfill 13 may be disposed between the carrier 10 and the package 12. The underfill 13 may surround or cover the electrical contacts 12e. The package 12 may be exposed from the encapsulant 14. For example, a lateral surface 123 and a surface 122 (such as a top surface) of the package 12 may be exposed from the encapsulant 14.

The package 12 may be adjacent to the electronic component 11. The package 12 and the electronic component 11 may be overlapped along the X axis or in the horizontal direction. The lateral surface 144 of the encapsulant 14 may face toward the package 12. The package 12 may be in the vicinity of the electronic component 11. In some arrangements, the distance (such as the shortest distance) between the package 12 and the electronic component 11 may be less than about 300 micrometers (μm). For example, the distance may be about 200 μm to 300 μm.

The package 12 may be electrically connected to the carrier 10, and the electrical connections may be attained by way of solder bonding, Cu-to-Cu bonding, wire bonding, or hybrid bonding. For example, the package 12 may be electrically connected with the conductive pads 10p of the carrier 10 through electrical contacts 12e.

In some arrangements, the line spacing of the I/O connections of the package 12 may be smaller or finer than that of the carrier 10. For example, the value range of the L/S ratio of the I/O connections of the package 12 may be smaller than that of the carrier 10. In some arrangements, the line spacing of the I/O connections of the electronic component 11 may be different from that of the package 12.

The package 12 may include a memory package, such as a dynamic random access memory (DRAM) package, a static RAM (SRAM) package, a read-only memory (ROM) package, a flash memory package, a magnetoresistive RAM (MRAM) package, etc. However, the inventive concept is not limited thereto. For example, the package 12 may be or include other types of packages, such as a transceiver package, a processing package, a networking package, a voltage regulating package (which may provide a regulated voltage), etc.

In some arrangements, the package 12 may include a carrier 12c, a component 12a, and an encapsulant 12m. The carrier 12c may be configured to provide structural support for the component 12a and the encapsulant 12m. The component 12a may include one or more memory dies. The component 12a may include a laminate stack. For example, FIG. 1A-1 may illustrate only the outermost memory die, providing a focused view of its structure and layout without depicting the underlying or adjacent dies. In some arrangements, the component 12a may include other types of dies. The encapsulant 12m may be disposed over the carrier 12c and cover the component 12a. The encapsulant 12m may include a material as listed above with respect to the encapsulant 14. In some arrangements, the encapsulant 12m may include a material different from that of the encapsulant 14.

FIG. 1B illustrates a perspective view of an electronic device in accordance with some arrangements of the present disclosure. In some arrangements, the electronic device 1a′ shown in FIG. 1A-1 may have a perspective view as depicted in FIG. 1B. Additionally, in some arrangements, a cross-sectional view of the electronic device in FIG. 1B taken along the line AA′ is shown in FIG. 1A-1.

A portion of the carrier 10 may be covered by the encapsulant 14, while another portion of the carrier 10 may be exposed. For example, approximately half of the carrier 10 may be encapsulated by the encapsulant 14, with the remaining half left uncovered.

The encapsulant 14 and the package 12 may be overlapped along the X axis or in the horizontal direction. The encapsulant 14 and the package 12 may not be overlapped along the Y axis or in the vertical direction. For example, the encapsulant 14 and the package 12 may share space side-by-side horizontally over the carrier 10, and they may not overlap when viewed from a vertical perspective. This spatial arrangement ensures clear separation between the encapsulant 14 and the package 12, which may be important for maintaining structural integrity or meeting specific design requirements.

FIG. 1C illustrates a perspective view of an electronic device in accordance with some arrangements of the present disclosure. In some arrangements, the electronic device 1a′ shown in FIG. 1A-1 may have a perspective view as depicted in FIG. 1C. Additionally, in some arrangements, a cross-sectional view of the electronic device in FIG. 1C taken along the line AA′ is shown in FIG. 1A-1. The electronic device in FIG. 1C is similar to the electronic device in FIG. 1B, except for the differences provided below.

The encapsulant 14 may include extensions 14t1 and 14t2. The extensions 14t1 and 14t2 may extend from the outline or boundary of the lateral surface 144 of the encapsulant 14. The extensions 14t1 and 14t2 may be integral parts of the encapsulant 14. For example, the encapsulant 14 may include a monolithic structure, meaning it is formed as a single, unified piece without any joints or seams. For example, the encapsulant 14, the extensions 14t1 and 14t2 may be formed as a single integrated unit during the same selective molding process. For example, the encapsulant 14, the extensions 14t1 and 14t2 may be co-molded as a single piece in one selective molding process. Consequently, the extension 14t1 and the encapsulant 14 may be seamlessly connected, exhibiting no visible boundaries or separations between them. Similarly, the extension 14t2 and the encapsulant 14 may also form a seamless connection. This seamless integration can enhance the structural integrity and overall performance of the encapsulant 14. The extension 14t1 may include a surface 145 facing away from the boundary of the lateral surface 144. The extension 14t2 may include a surface 146 facing away from the boundary of the lateral surface 144. The surface 146 and the surface 145 may be substantially aligned with each other.

In some arrangements, the extensions 14t1 and 14t2 may each include a wall structure, such as a vertical, flat, and planar structure. For example, the extensions 14t1 and 14t2 may each include a rectangle or straight plane. Additionally, the dimensions and materials of these wall structures can be varied to suit different design requirements or functional purposes.

In some arrangements, the boundary of the lateral surface 144 and the extension 14t1 may form a step, a notch, or a recessed corner. A corner of the package 12 may be received in the recessed corner. In some arrangements, the outline or boundary of the package 12 may closely align with, or nearly touch, the recessed corner, thereby enhancing the stability and alignment of the package 12 within the overall assembly. Similarly, the boundary of the lateral surface 144 and the extension 14t2 may form a step, a notch, or a recessed corner.

The extensions 14t1 and 14t2 may be disposed on opposite sides of the package 12. The encapsulant 14 may surround or be disposed along three sides of the package 12. For example, the encapsulant 14 and the extensions 14t1 and 14t2 may define a space for accommodating the package 12. In some arrangements, the lateral surface 123 may face away from the encapsulant 14. In some arrangements, the lateral surface 123 may be recessed or set back relative to the surfaces 146 and 145. In some arrangements, the lateral surface 123 may be substantially aligned with the surfaces 146 and 145.

The encapsulant 14 and the package 12 may be overlapped along the X axis or in the horizontal direction. The encapsulant 14 and the package 12 may be overlapped along the Y axis or in the vertical direction. This overlapping arrangement can enhance the structural integrity and protection of the package 12 by providing additional coverage and support on multiple sides. Furthermore, the size of the package 12 is not necessarily constrained by the dimensions of the encapsulant 14. This flexibility allows for greater design versatility and optimization of both components to meet specific functional and spatial requirements.

FIG. 1D illustrates a perspective view of an electronic device in accordance with some arrangements of the present disclosure. In some arrangements, the electronic device 1a′ shown in FIG. 1A-1 may have a perspective view as depicted in FIG. 1D. Additionally, in some arrangements, a cross-sectional view of the electronic device in FIG. 1D taken along the line AA′ is shown in FIG. 1A-1. The electronic device in FIG. 1D is similar to the electronic device in FIG. 1C, except for the differences provided below.

The size of the package 12 may be greater than the space or boundaries defined by the encapsulant 14. For example, the package 12 may protrude outside of the space or boundaries defined by the encapsulant 14. For example, a dimension of the package 12 measured along the X axis or in the horizontal direction may be greater than a dimension of the extension 14t1 (or the extension 14t2 ) measured along the X axis or in the horizontal direction. For example, the lateral surface 123 of the package 12 may protrude beyond or extend past the surface 146 and the surface 145.

The three-dimensional form factors of the protruding section can be strategically chosen. The protruding section can enhance thermal management by providing an increased surface area for heat dissipation. In certain configurations, this protrusion allows for visual inspection or electrical probing from a side view without the need to remove or damage the encapsulant 14, thereby facilitating more efficient and non-invasive quality control processes. Additionally, in some designs, the package 12 may incorporate components such as sensors or antennas that require exposure, or partial exposure, to the external environment to operate effectively. These components can be strategically positioned on the protruding section to optimize their functionality.

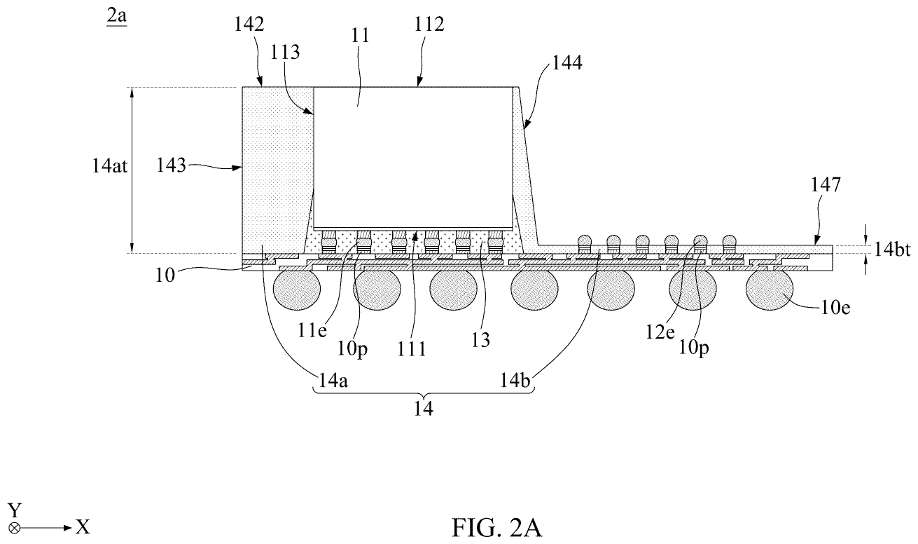

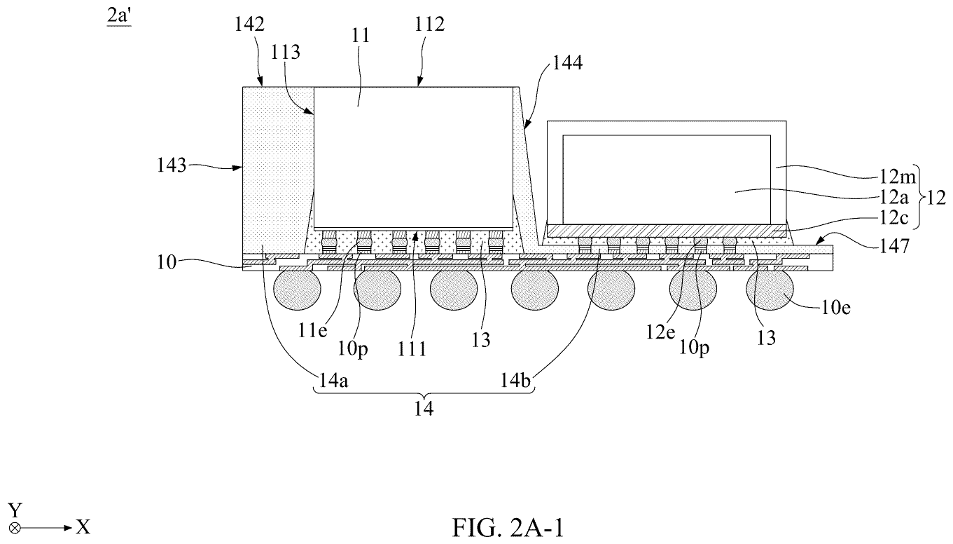

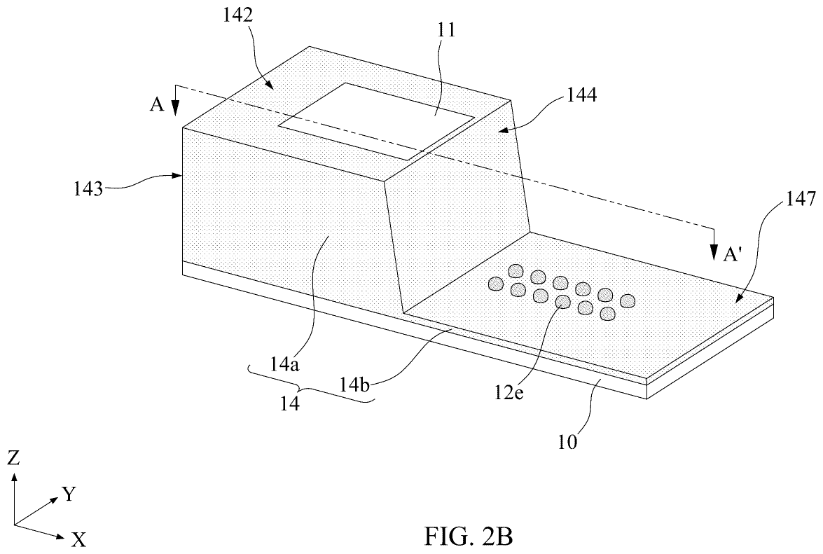

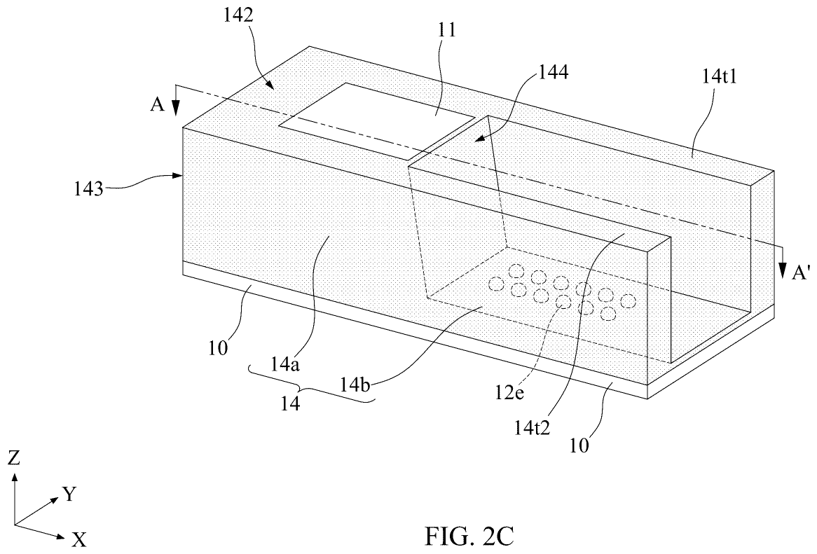

FIG. 2A illustrates a cross-sectional view of an electronic device 2a in accordance with some arrangements of the present disclosure. The electronic device 2a is similar to the electronic device 1a in FIG. 1A, except that the encapsulant 14 extends between opposite sides of the carrier 10. For example, the width, overall coverage area, or footprint of the encapsulant 14 can be designed to correspond to, match, or equal the width, overall coverage area, or footprint of the carrier 10.

For example, the encapsulant 14 may have a surface 147 connected with the boundary of the lateral surface 144. The lateral surface 144 may be connected between the surfaces 142 and 147 of the encapsulant 14. In some arrangements, the surface 147 may be substantially parallel to the surface 142. The surfaces 142 and 147 may be at different elevations with respect to the carrier 10. For example, the surface 142 could be situated at a higher elevation compared to the surface 147 when measured with respect to the carrier 10. Conversely, the surface 147 may be located at a lower elevation than the surface 142 relative to the carrier 10.

For example, the encapsulant 14 may comprise portions or regions 14a and 14b. The portions 14a and 14b may have different or varying thicknesses. The portion 14a may be a relatively thicker portion and the portion 14b may be a relatively thinner portion. For example, the thickness 14at of the portion 14a may be greater than the thickness 14bt of the portion 14b. The relatively thicker portion and the relatively thinner portion may be connected through the lateral surface 144.

Specifically, the portion 14a may cover or surround the electronic component 11, and the portion 14b may cover or surround the conductive pads 10p located beneath the electrical contacts 12e. In some arrangements, the height or thickness of the conductive pads 10p may be substantially equal to the thickness 14bt of the portion 14b. For example, the top surfaces of the conductive pads 10p may be substantially coplanar or aligned with the surface 147 of the encapsulant 14. The electrical contacts 12e may be disposed over the surface 147 of the encapsulant 14. Each of the electrical contacts 12e may be disposed over a corresponding one of the conductive pads 10p. This ensures that the encapsulant 14 provides adequate protection and adhesion across the carrier 10, while simultaneously preserving the access for electrical connections, thereby enhancing the structural integrity and durability of the electronic device 2a.

FIG. 2A-1 illustrates a cross-sectional view of an electronic device 2a′ in accordance with some arrangements of the present disclosure. The electronic device 2a′ is similar to the electronic device 2a in FIG. 2A, except that the electronic device 2a′ further includes the package 12.

The package 12 may be disposed over the surface 147 of the encapsulant 14. The underfill 13 may be disposed over the surface 147 of the encapsulant 14. The underfill 13 may surround or cover the electrical contacts 12e. The underfill 13 may be disposed between the package 12 and the surface 147 of the encapsulant 14. The underfill 13 may be spaced apart from the carrier 10 by the encapsulant 14. The underfill 13 may be spaced apart from the conductive pads 10p by the encapsulant 14.

The encapsulant 14 may extend from the surface 113 of the electronic component 11 to beneath the package 12. The encapsulant 14 may also extend beneath the underfill 13.

The underfill 13 under the electronic component 11 may be situated at a lower elevation compared to the underfill 13 under the package 12 when measured with respect to the carrier 10.

FIG. 2B illustrates a perspective view of an electronic device in accordance with some arrangements of the present disclosure. In some arrangements, the electronic device 2a shown in FIG. 2A may have a perspective view as depicted in FIG. 2B. Additionally, in some arrangements, a cross-sectional view of the electronic device in FIG. 2B taken along the line AA′ is shown in FIG. 2A.

For example, the encapsulant 14 may cover the entire surface area, with the exception of the specific locations where the electronic component 11 and the electrical contacts 12e are positioned. In this configuration, both the electronic component 11 and the electrical contacts 12e remain exposed and are not covered by the encapsulant 14. This selective coverage ensures that the electrical contacts 12e are accessible for electrical connection, while the rest of the surface is protected by the encapsulant 14 to provide mechanical support and protection from environmental factors.

FIG. 2C illustrates a perspective view of an electronic device in accordance with some arrangements of the present disclosure. In some arrangements, the electronic device 2a shown in FIG. 2A may have a perspective view as depicted in FIG. 2C. Additionally, in some arrangements, a cross-sectional view of the electronic device in FIG. 2C taken along the line AA′ is shown in FIG. 2A. The electronic device in FIG. 2C is similar to the electronic device in FIG. 2B, except that the encapsulant 14 may include extensions 14t1 and 14t2 .

In some arrangements, the extensions 14t1 and 14t2 may extend from the portion 14a. The extensions 14t1 and 14t2 may extend onto the portion 14b. The extensions 14t1 and 14t2 may be disposed over the portion 14b. In some arrangements, the thicknesses of the extensions 14t1 and 14t2 may be substantially equal to the thickness (such as the thickness 14at in FIG. 2A) of the portion 14a.

The details of the extensions 14t1 and 14t2 are described above with respect to FIG. 1C, and will not be repeated herein for conciseness. In an assembled state (such as in some arrangements with the package 12), the size of the package 12 is not necessarily constrained by the dimensions of the encapsulant 14, as described above with respect to FIG. 1C.

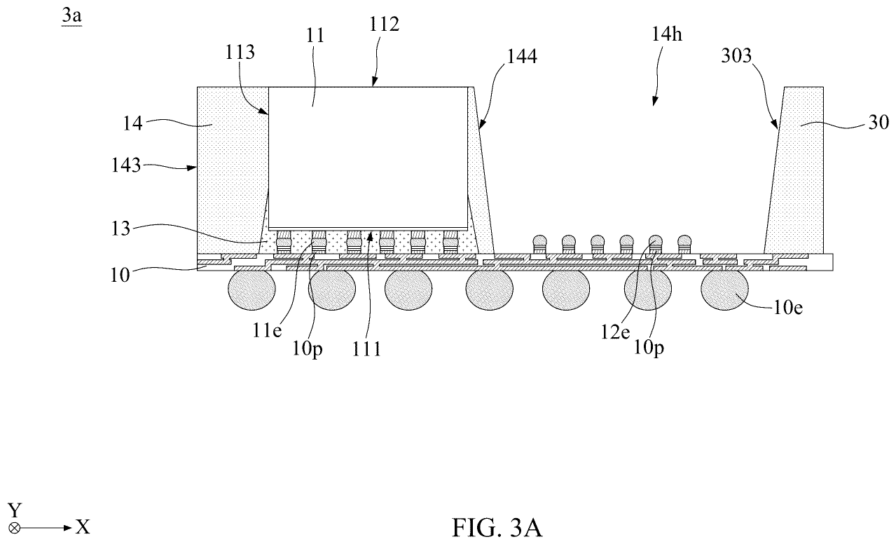

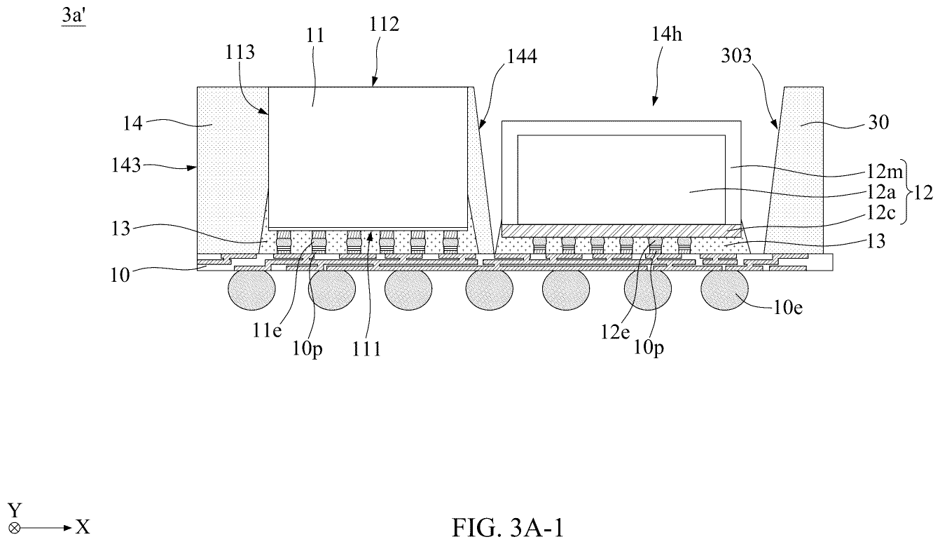

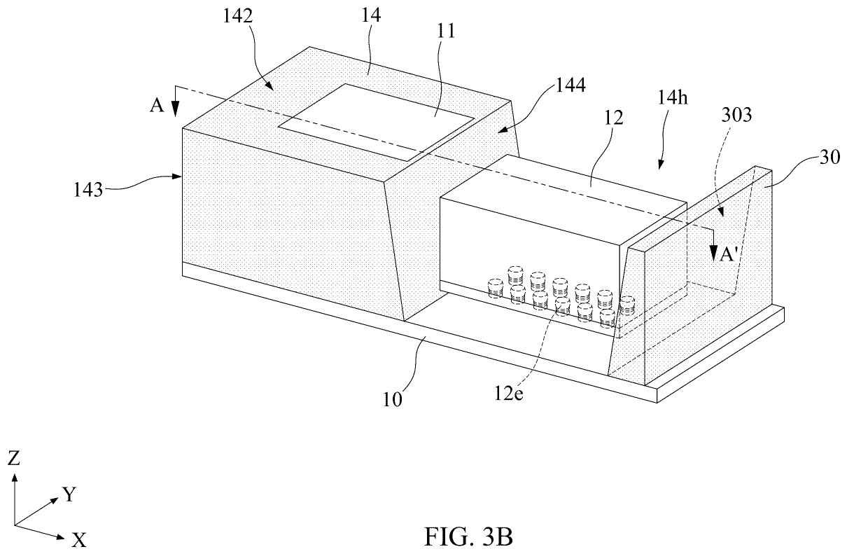

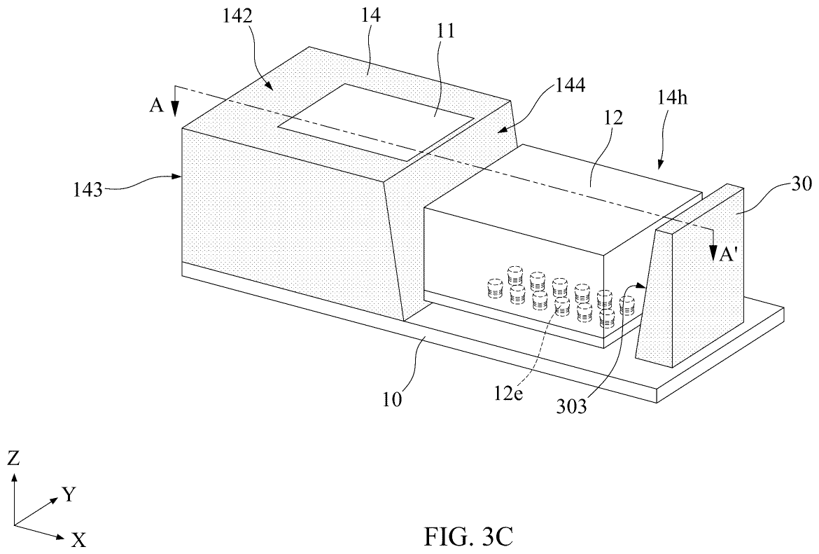

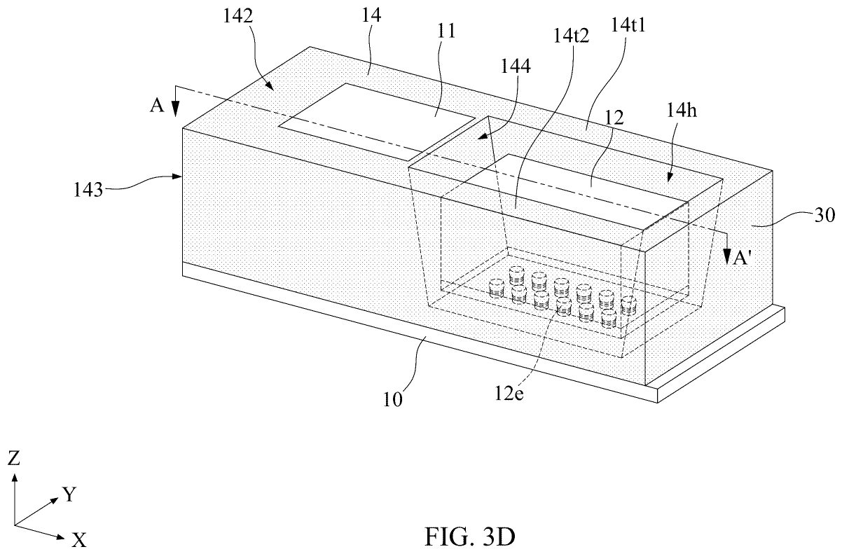

FIG. 3A illustrates a cross-sectional view of an electronic device 3a in accordance with some arrangements of the present disclosure. The electronic device 3a is similar to the electronic device 1a in FIG. 1A, except that the electronic device 3a further includes a wall structure 30.

The wall structure 30 may include a material as listed above with respect to the encapsulant 14. In some arrangements, the wall structure 30 may include a material different from that of the encapsulant 14. The wall structure 30 may be spaced apart from the encapsulant 14 by an opening 14h. The electrical contacts 12e may be exposed in the opening 14h. The opening 14h may include a slot, a gap, or a hole. In some arrangements, the opening 14h may include multiple slots, such as communication slots.

The wall structure 30 may have a lateral surface (or a sidewall) 303. The lateral surface 303 may be inclined with respect to the carrier 10, providing a slanted or tapered profile. The opening 14h may tapper toward the carrier 10. In some arrangements, the wall structure 30 may include pillars arranged in a vertical stack.

FIG. 3A-1 illustrates a cross-sectional view of an electronic device 3a′ in accordance with some arrangements of the present disclosure. The electronic device 3a′ is similar to the electronic device 3a in FIG. 3A, except that the electronic device 3a′ further includes the package 12.

The package 12 may be disposed in the opening 14h. The wall structure 30 and the encapsulant 14 may be disposed on opposite sides of the package 12.

FIG. 3B illustrates a perspective view of an electronic device in accordance with some arrangements of the present disclosure. In some arrangements, the electronic device 3a′ shown in FIG. 3A-1 may have a perspective view as depicted in FIG. 3B. Additionally, in some arrangements, a cross-sectional view of the electronic device in FIG. 3B taken along the line AA′ is shown in FIG. 3A-1.

In some arrangements, the wall structure 30 and the encapsulant 14 may not be connected. A dimension of the package 12 measured along the Y axis or in the vertical direction may be less than a dimension of the wall structure 30 measured along the Y axis or in the vertical direction.

FIG. 3C illustrates a perspective view of an electronic device in accordance with some arrangements of the present disclosure. In some arrangements, the electronic device 3a′ shown in FIG. 3A-1 may have a perspective view as depicted in FIG. 3C. Additionally, in some arrangements, a cross-sectional view of the electronic device in FIG. 3C taken along the line AA′ is shown in FIG. 3A-1. The electronic device in FIG. 3C is similar to the electronic device in FIG. 3B, except that a dimension of the package 12 measured along the Y axis or in the vertical direction may be greater than a dimension of the wall structure 30 measured along the Y axis or in the vertical direction.

FIG. 3D illustrates a perspective view of an electronic device in accordance with some arrangements of the present disclosure. In some arrangements, the electronic device 3a′ shown in FIG. 3A-1 may have a perspective view as depicted in FIG. 3D. Additionally, in some arrangements, a cross-sectional view of the electronic device in FIG. 3D taken along the line AA′ is shown in FIG. 3A-1. The electronic device in FIG. 3D is similar to the electronic device in FIG. 3B, except that the encapsulant 14 may include the extensions 14t1 and 14t2.

The wall structure 30 and the encapsulant 14 may be connected through the extensions 14t1 and 14t2. The wall structure 30 and the encapsulant 14 may form an enclosure wall. The details of the extensions 14t1 and 14t2 are described above with respect to FIG. 1C, and will not be repeated herein for conciseness.

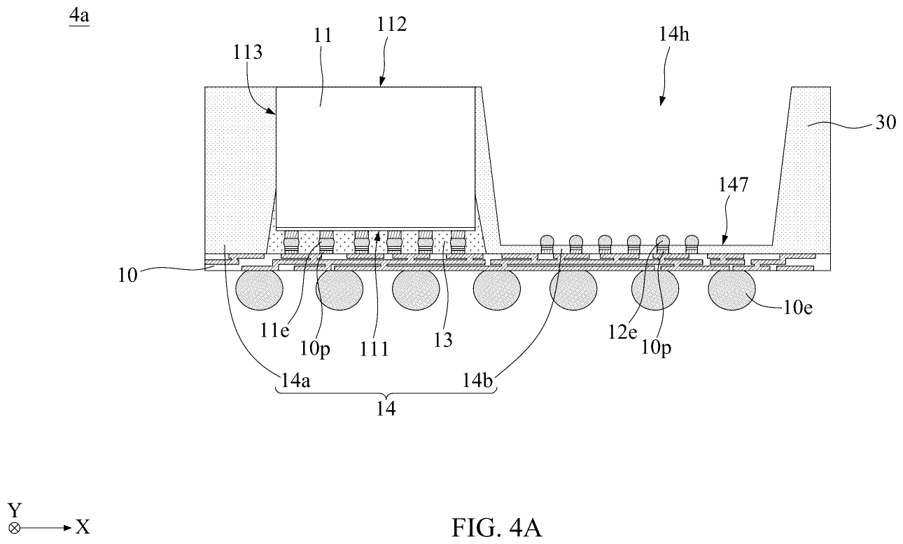

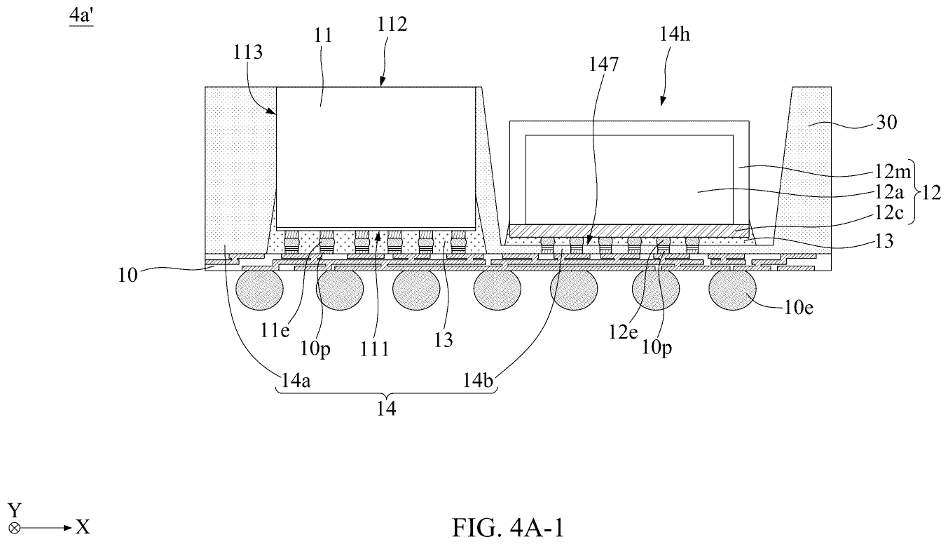

FIG. 4A illustrates a cross-sectional view of an electronic device 4a in accordance with some arrangements of the present disclosure. The electronic device 4a is similar to the electronic device 2a in FIG. 2A, except that the electronic device 3a further includes the wall structure 30. The wall structure 30 may be disposed over the surface 147. The details of the wall structure 30 are described above with respect to FIG. 3A, and will not be repeated herein for conciseness.

FIG. 4A-1 illustrates a cross-sectional view of an electronic device 4a′ in accordance with some arrangements of the present disclosure. The electronic device 4a′ is similar to the electronic device 4a in FIG. 4A, except that the electronic device 4a′ further includes the package 12.

The package 12 may be disposed in the opening 14h. The wall structure 30 and the encapsulant 14 may be disposed on opposite sides of the package 12.

In some arrangements, the electronic device 4a and/or the electronic device 4a′ may include the extensions (such as the extensions 14t1 and 14t2 in FIG. 3D) connecting the wall structure 30 and the encapsulant 14.

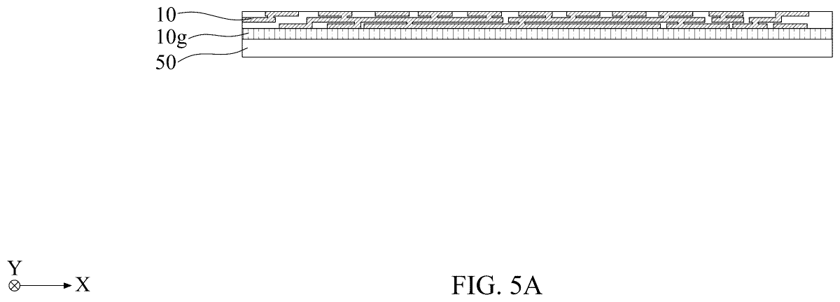

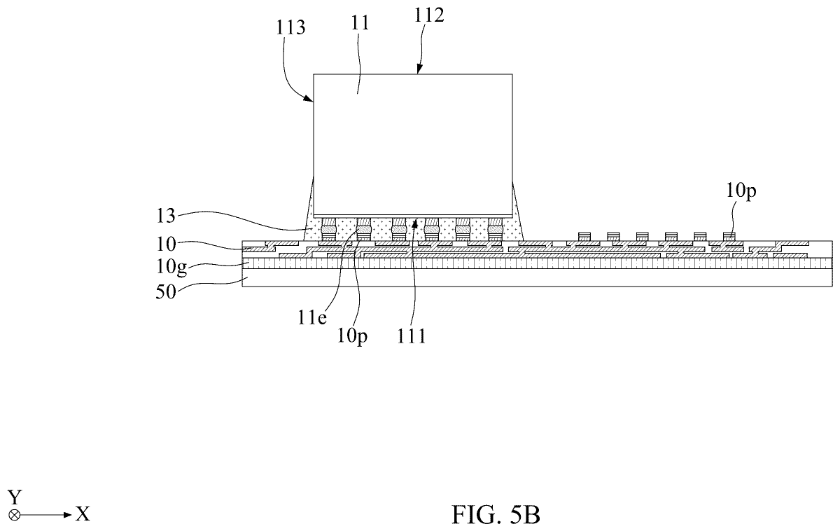

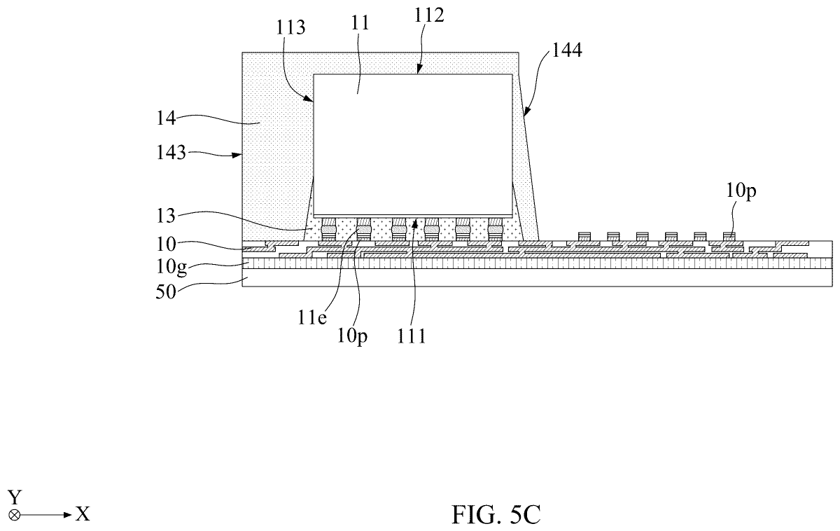

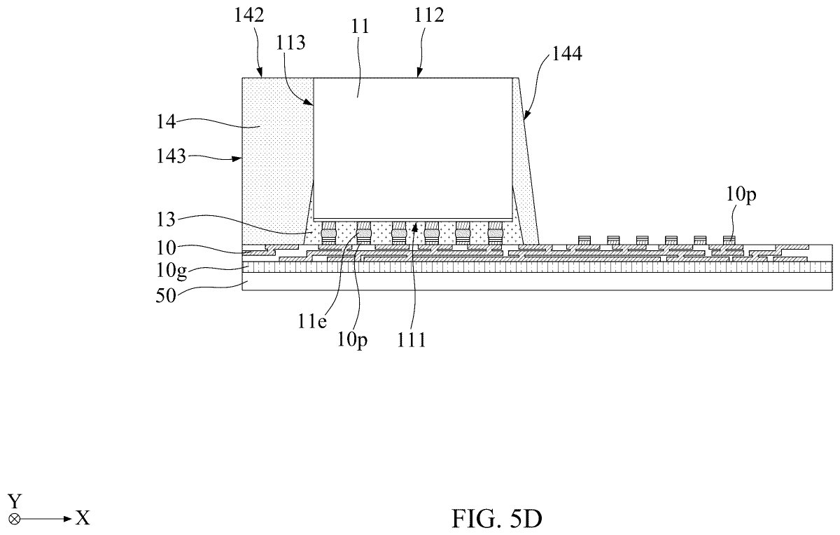

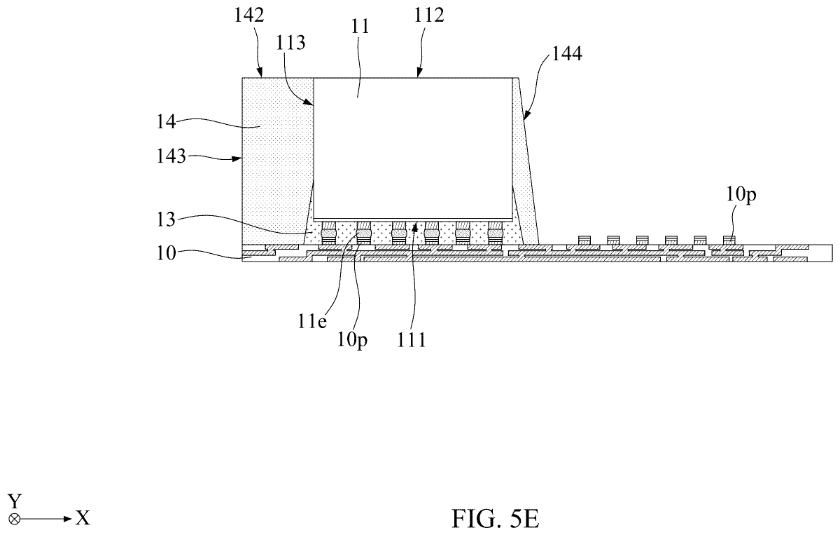

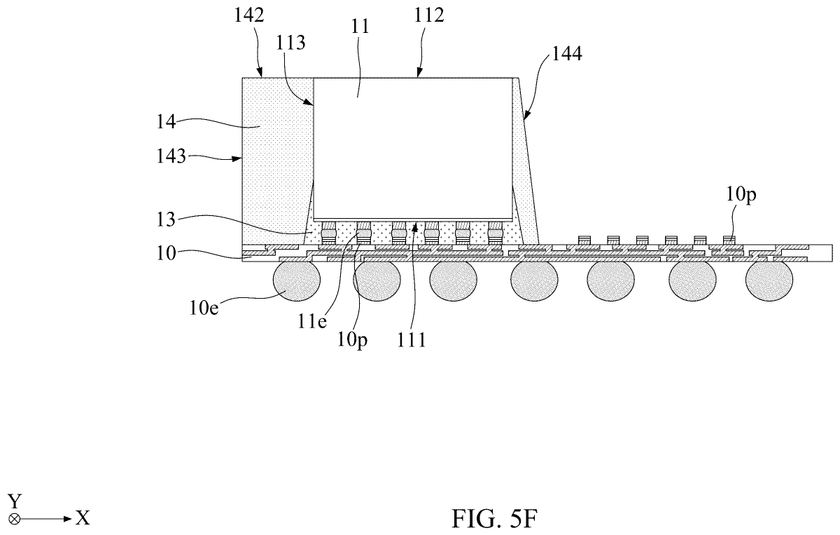

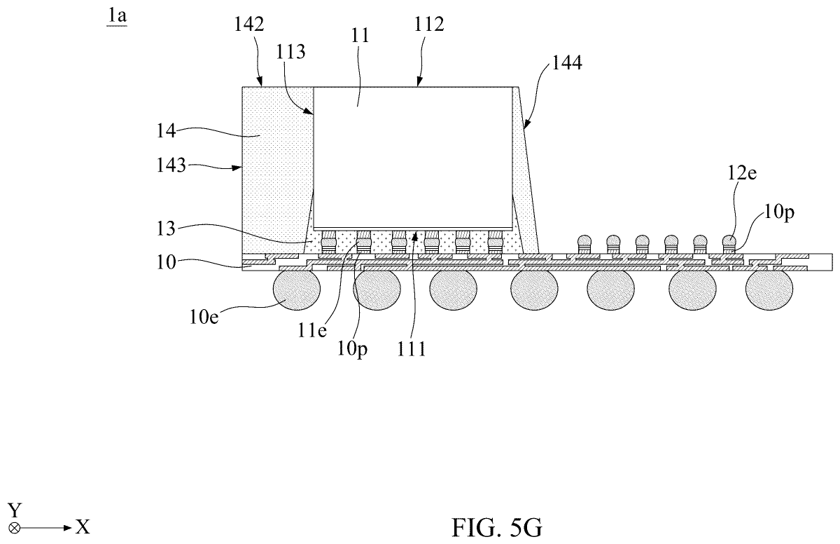

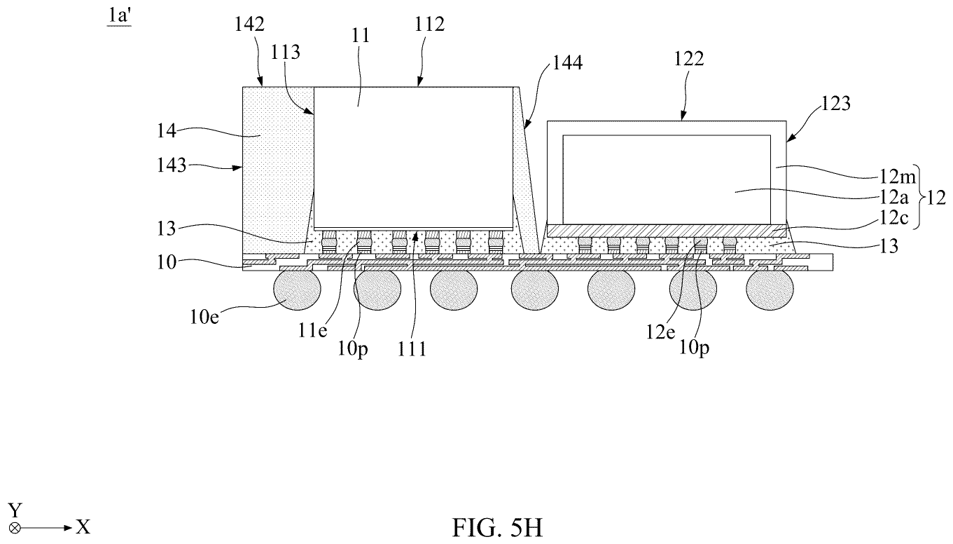

FIGS. 5A, 5B, 5C, 5D, 5E, 5F, 5G, and 5H are cross-sections of one or more stages of a method of manufacturing an electronic device in accordance with some arrangements of the present disclosure. At least some of these figures have been simplified to better understand the aspects of the present disclosure. In some arrangements, the electronic device 1a′ may be manufactured through the steps illustrated in FIGS. 5A, 5B, 5C, 5D, 5E, 5F, 5G, and 5H.

Referring to FIG. 5A, a temporary carrier 50 may be provided (e.g., manufactured or obtained). The temporary carrier 50 may be a glass carrier, a metal carrier, a ceramic carrier, or other suitable carriers. The temporary carrier 50 may include a panel, and the size thereof can be approximately 300 mm square, 500 mm square, 600 mm square, or larger. For example, the electronic device 1a′ may be implemented using a panel level packaging (PLP) process. In the PLP process, a panel is used to fabricate multiple semiconductor packages simultaneously. Compared to conventional wafer-level packaging (WLP), the use of a panel allows for greater production throughput and improved material utilization, as a result of the increased substrate size. The rectangular substrate is typically formed of an organic laminate material or a glass-based substrate, and may include pre-defined cutting streets (saw lanes) along rows and columns to facilitate singulation after encapsulation and other back-end processes.

The carrier 10 may be formed over the temporary carrier 50. The carrier 10 may be attached to the temporary carrier 50 through an adhesive layer 10g. The adhesive layer 10g may include a die attach film (DAF), a glue, a bonding layer, an underfill, or another suitable material.

In some arrangements, due to the rectangular geometry of the panel, electroplating during RDL formation may result in charge accumulation at the corners, leading to unique microstructural effects on the routing lines near the panel edges—effects that do not occur on circular wafers. To compensate for plating non-uniformity at the panel corners, dummy structures may be densely distributed in these regions. Furthermore, the panel's cutting streets are typically aligned parallel or perpendicular to the panel edges, which is structurally distinct from the dicing paths on wafers.

Referring to FIG. 5B, the electronic component 11 may be disposed over the carrier 10. The underfill 13 may be disposed between the electronic component 11 and the carrier 10. In some arrangements, more than two electronic devices may be placed on the carrier 10 in a batch and subjected to similar or identical processes in the manufacturing method. For example, the electronic components 11 may be arranged in an N×M array.

In some arrangements, compared to WLP, PLP is based on a rectangular panel substrate on which multiple components are arranged in an N×M array, with each row and each column containing the same number of components. This uniform grid arrangement is a characteristic feature of PLP and differs from WLP, where die density is typically higher at the wafer center and lower at the periphery. For example, WLP includes a central region including a relatively higher density of dies and a peripheral region including a relatively lower density of dies. In PLP, the outermost row and the outermost column may share a single component located at the panel corner—a layout that is uncommon on a circular wafer.

Referring to FIG. 5C, the encapsulant 14 may be disposed over the carrier 10 to cover the electronic component 11 and the underfill 13. In some arrangements, the encapsulant 14 may be formed by a molding technique, such as selective molding, localized molding, or partial molding. For example, the encapsulant 14 may be selectively molded in specific areas on the carrier 10, rather than being applied to cover the entire surface of the carrier 10. The encapsulant 14 may be disposed selectively on targeted areas of the carrier 10, while leaving other areas exposed.

Referring to FIG. 5D, a planarization operation or a grinding operation may be performed to remove a portion of the encapsulant 14, exposing the surface 112 of the electronic component 11.

Referring to FIG. 5E, the temporary carrier 50 and the adhesive layer 10g may be removed, and the carrier 10 may be exposed.

Referring to FIG. 5F, the electrical contact 10e may be formed over the carrier 10.

Referring to FIG. 5G, the electrical contact 12e may be formed over the carrier 10, forming the electronic device 1a. In some arrangements, the electronic device 1a may be shipped to a different production line for the placement of the package 12.

Referring to FIG. 5H, the package 12 may be disposed over the carrier 10. In some arrangements, an electrical test can be performed on the carrier 10 before mounting the package 12. In some arrangements, an electrical test may be conducted after the package 12 has been disposed over the carrier 10. If either the package 12 or the carrier 10 is found to be defective during this test, the method includes disengaging and removing the package 12 from the opening to allow for replacement or further inspection.

A singulation operation may be performed. The electronic device assembly may be singulated or separated into a plurality of individual units or segmented parts in a singulation operation. In some arrangements, the singulation operation may be performed using a saw blade or laser cutting tool.

Conventionally, the package (such as a memory package) is molded together with the IC die within the encapsulant. During subsequent processing steps, the package is susceptible to damage that cannot be rectified by removing or replacing the package after the molding process. Consequently, this conventional approach introduces significant challenges and often results in higher manufacturing costs and lower production yields due to increased waste and rework from defective packages.

According to some arrangements of the present disclosure, the invention employs a selective molding process that offers greater flexibility to manufacture molding compounds of different heights at various locations. The electrical contacts for connecting another component (such as a memory package) are not covered by the molding compound. This allows electrical testing of the RDL before placing the memory package, thereby facilitating early defect detection, reducing costs, and improving yield. Furthermore, because the electrical contacts are already exposed, there is no need to create an opening in the molding compound to access them. This eliminates an additional processing step, further lowering production costs and minimizing potential damage to the device during manufacturing.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and the lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a redistribution layer (RDL) having a plurality of conductive pads;
a chip disposed over the RDL; and
an encapsulant disposed over the RDL, wherein the encapsulant includes a first portion surrounding the chip and a second portion surrounding the plurality of conductive pads, and wherein the first portion and the second portion have different thicknesses.

2. The electronic device of claim 1, wherein the first portion and the second portion are connected through a lateral surface of the encapsulant, and wherein the lateral surface is inclined with respect to the RDL.

3. The electronic device of claim 1, wherein a backside surface of the chip is substantially coplanar with a surface of the first portion.

4. The electronic device of claim 3, wherein a top surface of the plurality of conductive pads is substantially coplanar with a surface of the second portion.

5. The electronic device of claim 1, further comprising:
a memory package disposed over the second portion and electrically connected with the plurality of conductive pads.

6. The electronic device of claim 1, wherein the encapsulant comprises an extension from the first portion onto the second portion.

7. The electronic device of claim 6, further comprising:
a memory package disposed over the second portion and protruding beyond the extension.

8. The electronic device of claim 6, wherein the encapsulant further comprises a wall structure connected with the extension.

9. The electronic device of claim 8, further comprising:
a memory package disposed in an opening defined by the wall structure and the extension.

10. An electronic device, comprising:
a redistribution layer (RDL);
a chip disposed over the RDL;
an encapsulant covering the chip; and
a memory package disposed over the RDL and uncovered by the encapsulant, wherein the memory package extends past the encapsulant.

11. The electronic device of claim 10, wherein the encapsulant defines a space, and the memory package is partially received in the space and partially protrude outside of the space.

12. The electronic device of claim 10, wherein the memory package and the encapsulant are overlapped to each other in two directions.

13. The electronic device of claim 10, wherein the encapsulant extends beneath the memory package.

14. The electronic device of claim 13, further comprising:
a first underfill disposed between the encapsulant and the memory package.

15. The electronic device of claim 14, further comprising:
a second underfill disposed between the chip and the RDL.

16. The electronic device of claim 13, wherein the encapsulant includes a relatively thicker portion and a relatively thinner portion.

17. A method for manufacturing an electronic device, comprising:
providing a redistribution layer (RDL) having a plurality of conductive pads;
disposing a chip over the RDL; and
forming an encapsulant covering the chip without covering the plurality of conductive pads.

18. The method of claim 17, wherein the encapsulant includes a first portion surrounding the chip and a second portion surrounding the plurality of conductive pads, and wherein the first portion and the second portion have different thicknesses.

19. The method of claim 17, wherein the encapsulant is formed by a selective molding process.

20. The method of claim 19, further comprising:
forming an extension of the encapsulant, wherein the encapsulant and the extension of the encapsulant are formed as a single integrated unit during the selective molding process.
